(19) United States
(12) Patent Application Publication
(10) Pub. No.: US 2014/0167578 A1
(43) Pub. Date: Jun. 19, 2014

(54) Computer Chassis

(71) Applicant: PSSC LABS, Lake Forest, CA (US)

(72) Inventors: Janice Lesser, Lake Forest, CA (US); Larry Lesser, Lake Forest, CA (US)

(73) Assignee: PSSC LABS, Lake Forest, CA (US)

(21) Appl. No.: 13/841,860

(22) Filed: Mar. 15, 2013

Related U.S. Application Data
(60) Provisional application No. 61/739,591, filed on Dec. 19, 2012.

(51) Int. Cl. H05K 5/02; H05K 5/00

(52) U.S. Cl. CPC H05K 5/0247; H05K 5/0213; H05K 5/00
USPC 312/223.2; 312/223.6; 312/223.5

(57) ABSTRACT

A computer chassis has a body with variable components. The chassis is accessible from the front or back of a casing or cabinet through the use of gripping loops. Further, each cooling fan, mounted on a rail, is removable, thus making the fans' positions variable and a back plane unnecessary. The chassis is arranged such that hard drives may be configured into different orientations through movable components, altering the size and number of hard drives with ease. Because the position of each hard drive is also variable and removable, connectors are loose and not attached to a fixed back plane. A power controller may be utilized through both the front and back of the panel.

### CROSS-REFERENCE TO RELATED APPLICATIONS

This application claims the benefit of U.S. Provisional Application No. 61/739,591, filed Dec. 19, 2012, and titled “Computer Chassis,” which is incorporated by reference in its entirety herein.

### BACKGROUND

The present invention relates to a computer chassis, especially to an improved computer chassis with variable internal components and multiple access directions.

A computer chassis generally encloses a computer's components. Conventionally, on one side of the enclosure, one or more drive bays are provided to insert various hard drives or other similar components into a back plane. The back plane is essentially a static configuration including various ports along a strip to permit the direct plug-in connection of multiple hard drives. The back plane usually runs through approximately the middle of the enclosure from one side to the other, or along an edge of the enclosure. The various electronic components and wirings are then positioned around the back plane. Once created, the arrangement of the components is static and not reconfigurable.

### SUMMARY

A computer chassis is disclosed that is installed or removed from the front or back of a rack cabinet. This provides faster and easier installation and maintenance of computer systems. Hard drives of differing sizes can be operatively mounted on the base plate of a computer chassis without altering the configuration of the chassis.

The computer chassis may be removable and accessible from more than one side, e.g., the front and back of a tower. In addition, various control features, inputs, outputs, and indicators, such as power and reset buttons, network and power indicators, etc. may be located on same sides that provide access, such as, for example, to the front and back of the chassis. This allows a user to easily service the computer components from multiple sides of the chassis. Therefore, more flexibility is achieved with regard to the chassis, as well as placing the chassis within a room of one or more chassis.

The chassis according to an embodiment does not include a backplane. By removing the back plane, air flow and circulation through the components is improved. The new configuration improves circulation and manages the heat generated from the various components. One or more fans may be included in place of the back plane to further improve circulation. The air flow through the chassis is unique, allowing proper cooling of components. A power supply may contain its own cooling fan. In addition, the cooling fans in the center of the chassis may be moveable to different locations, altering their spacing and orientation.

The chassis according to an embodiment is fully flexible regarding the hard drive installation of various sized hard drives, for example 3.5, 2.5 inch, or a combination of both hard drives. The absence of a back plane allows more room in the chassis for components, and for changeability of those components. Because the frame may also be stationary with adjustable portions to fit to a rack's depth, so that the frame and the various components are reusable. The system design allows a multitude of configuration options using non-proprietary components, as opposed to a design where only specific components may be utilized.

Features from any of the above mentioned embodiments may be used in combination with one another in accordance with the instant disclosure. Any described feature herein may be used along or in combination, recombination, and/or a sub-combination than that disclosed. The illustrated figures and associated description are exemplary only. In addition, other features and advantages contemplated by the instant disclosure will become apparent to those of ordinary skill in the art through consideration of the ensuing description, the accompanying drawings, and the appended claims.

### BRIEF DESCRIPTION OF THE DRAWINGS

FIG. 1 shows a perspective view of an embodiment of computer chassis according to the instant disclosure.

FIG. 2 shows a front view of an embodiment of a computer chassis according to the instant disclosure.

FIG. 3 shows a back view of an embodiment of a computer chassis according to the instant disclosure.

FIG. 4 shows a top view of an embodiment of a computer chassis interior according to the instant disclosure.

FIG. 5 shows a cross-section view of an embodiment of a hard drive frame according to the instant disclosure.

FIG. 6 shows a top view of an embodiment of a computer chassis interior according to the instant disclosure.

FIG. 7 shows a perspective view of an embodiment of interchangeable hard drive frames according to the instant disclosure.

FIGS. 8A and 8B show a side view of an embodiment of a rolling sensor according to the instant disclosure.

FIG. 9 shows a top view of an embodiment of a computer chassis interior according to the instant disclosure.

### DETAILED DESCRIPTION

The following detailed description should be read with reference to the drawings, in which like elements in different drawings are identically numbered. The drawings, which are not necessarily to scale, depict selected preferred embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

A computer chassis 100 may comprise a rack 200 slidably inserted into a casing 105 located in a server tower cabinet 110. In an exemplary embodiment, the entire rack 200 may be incorporated into a casing 105 that further enhances access and interchangeability. Accordingly to embodiments described herein, an exemplary computer chassis may include modular parts that provide interchangeability that improves installation, access, upgrades, replacement, maintenance, etc. while reducing cost. The modular system may improve access to the interior cavity retaining system components. In an exemplary embodiment, three modular components are used, including a cabinet 110, casing 105, and rack 200. These components may be integrated into fewer components or may be excluded altogether, or additional components may also be included. For example, the rack may be connected directly to the cabinet 110, the casing 105 may be integrated into the cabinet 110, or the casing 105 may be integrated in to the rack 200.

In the exemplary embodiment, the cabinet 110 and casing 105 support the rack 200, while the rack 200 contains the system components. As shown, the cabinet 110 is a skeletal vertical support frame for the casing 105, which provides the horizontal support for the rack 200. The cabinet 110 permits casings 105 of various sizes to be positioned vertically in a given space. The casings 105 may be of various sizes and include spacers or other connection mechanisms so that they may fit within a given cabinet 110. The casing 105 may have two or more openings to permit access to the enclosed rack from more than one direction. The openings may be accessed through a cover or may cover the system components through the interaction with the rack 200. Alternatively, the chassis may provide direct access to the system components through one or more openings that is not covered.

As shown, the rack slides into the casing which is secured to the cabinet. Therefore, the casing 105 includes a through passage, such that the front and back are open. Access may be gained to the rack 200 through either the front or back of the cabinet. This configuration permits maintenance on the system from more than one direction. However, the exemplary configuration should not limit the invention, as access may be achieved through any two sides, including the top. The slide through configuration does provide easy manufacture, and connection to the casing and cabinet. The system may also include a switch or relay that indicates whether the rack is positioned within the casing. The switch may cut power to the system components if the rack is withdrawn or may be coupled to an indicator to indicate to a user that the rack is either properly and/or improperly positioned within the casing. System controls and indicators, such as power, reset, connection indicators, etc. may be provided on the rack visible or accessible to a user from the same side as access is provided. Therefore, if access is provided through a front and back of the chassis, the one or more control and/or indicators may also be included on both the front and back of the chassis. These controls and/or indicators may include the same functions, or may include a different set of functions. For example, access from a front panel may include additional controls than those provided from the rear, but a sub-set of controls may be the same, regardless of the direction of access.

The rack 200 may also provide dynamic configurability of the system components. The rack 200 may include connectors 160 that permit the location of the attached component to be selected at the time of installation, and reconfiguration after installation. Frames 180 associated with the given component may be used to hold the given component in a selected location. The frames 180 may be inserted into a construct within a portion of the rack that accommodates various configurations, sizes, and positions of one or more frames, such that the frames may be interchanged and repositioned by selecting a different accommodation on the rack.

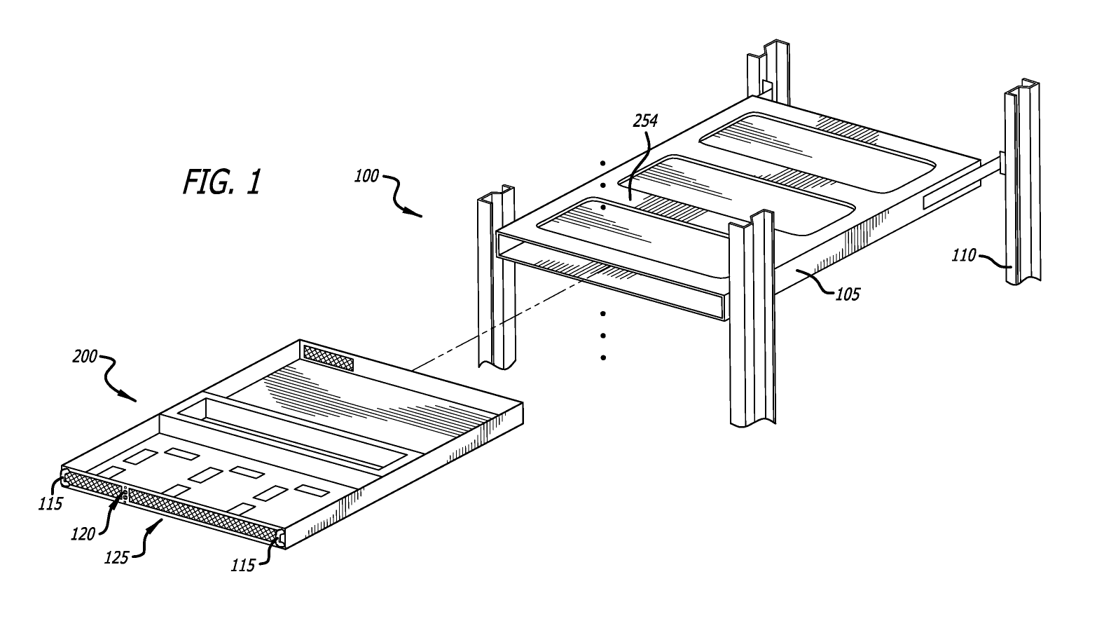

Referring to the exemplary embodiment of FIG. 1, a cabinet 110 may include one or more casings 105 bolted, screwed, or otherwise connected together. The cabinet 110 may be any support structure or frame for holding one or more casings 105 and/or racks 200. As shown, the casing 105 may be a generally rectangular box without a front or back panel. The rack 200, in an exemplary embodiment, may be one rack unit (1U) high, and inserted into a 23-inch deep casing 105. (A rack unit, U or RU, is a unit of measure used to describe the height of equipment intended for mounting in a rack. One rack unit is 1.75 inches high.) The rack mount frame may adjust to the depth of a rack 200. The casing 105 may include two or more flanged connectors with screw holes that permits the casing 105 to be attached at the flanges to a cabinet 110. The flanged connectors along the side of the casing 105 may be extendable and adjustable, allowing the rack mount frame to adjust to the depth of a rack 200. A rack 200 may then generally correspond to the interior size/shape of the casing 105. The rack 200 may slide into the casing 105 from two or more sides, including the front or back of the casing 105. In an exemplary embodiment, through the use of gripping surfaces 115, such as handles or hooks, a user may insert and remove the rack 200 from the casing 105 from one or more sides, such as the front or back, of the server tower cabinet 110. The rack 200 may include a bottom surface and side surfaces, but not a top surface, so that the interior of the rack 200 is easily accessible once slid from the casing 105. The open sides, such as the front and back, of the rack 200 corresponding to the open areas of the casing 105 may also include removable panels 125, 130 to provide alternative access to the interior of the rack 200 from one or both sides. This provides a user easy serviceability through access to the internal installed components at two or more sides, such as a front and back, of the cabinet 110. The removable panels 125, 130 may include ventilation holes 135 to further improve flow through the rack 200. The front and back of the rack 200 may include handles, hooks, or other gripping surfaces/features 115 to improve removal of the rack 200 from the casing 105.

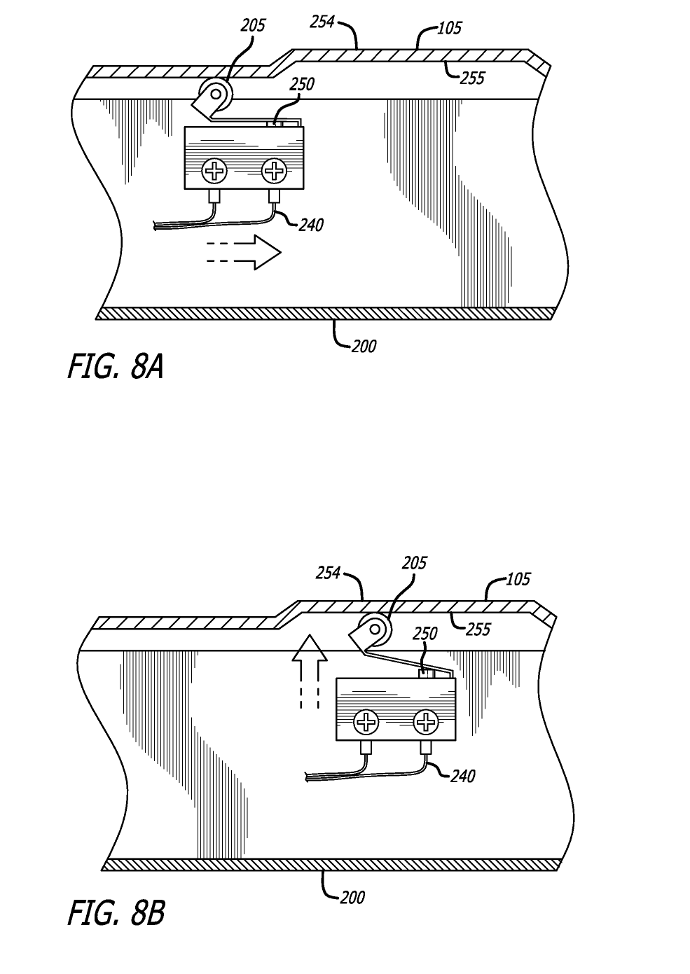

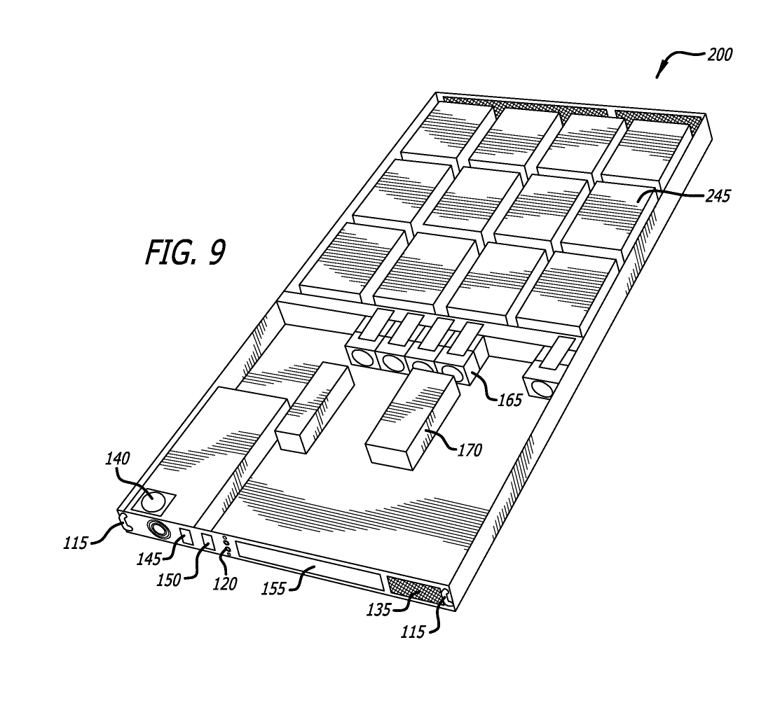

Optionally, a rack 200 may include components to ensure the rack 200 is secured to the casing 105. In one embodiment, as a user slides the rack 200 into the casing 105 attached to the server tower cabinet 110, a rolling pin 205 in the rack 200 mates with a corresponding depression in the interior of the casing 105 (shown in detail in FIGS. 8A and 8B) to alert the user that the rack 200 is properly and fully inserted into the casing 105. In an exemplary embodiment, the exterior of the casing 105 includes three indented panels, creating raised areas 254 between the panels. The rolling pin 205 slides into the corresponding area 255 in the interior of the casing 105.

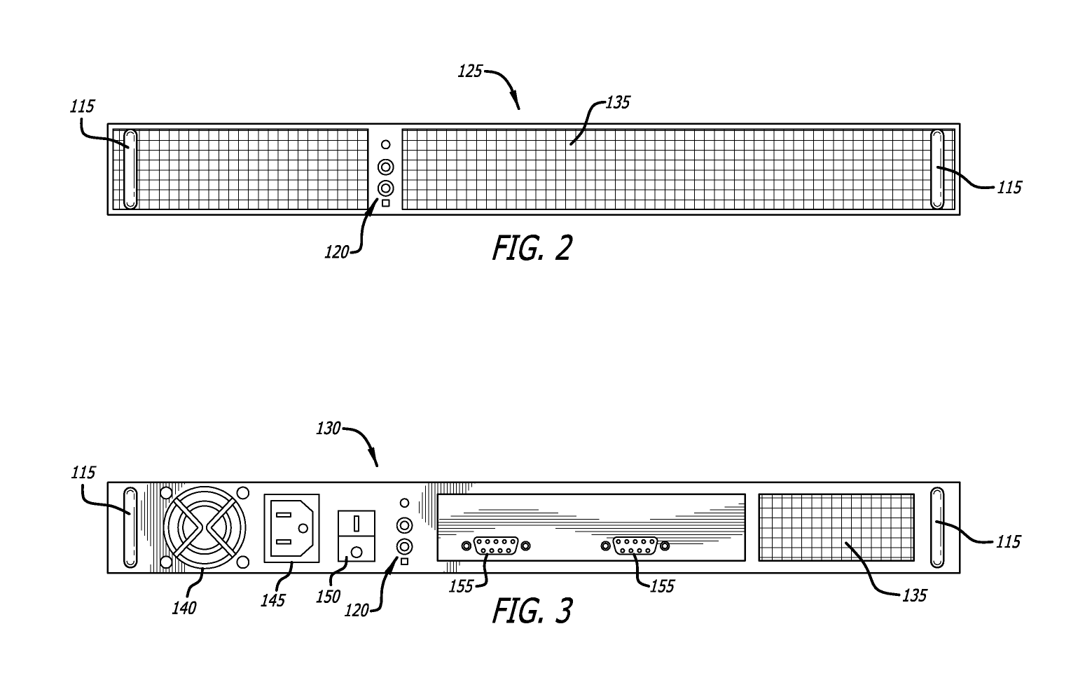

As shown in FIG. 2, the front panel 125 of the rack 200 may include a frame with ventilation holes 135, gripping surfaces 115, and control buttons 120. In an exemplary embodiment, the rack 200 provides access and control buttons 120, including control features (power and reset), and indicators (network and power), at both a front panel 125 and a back panel 130 of the rack 200. Therefore, a person servicing the device may gain access, control, and feedback from either side of the device requiring servicing. For example, if a person is attempting to access the hard drive area, a person can remove a front panel 125 to the rack and perform the necessary work (removing, replacing, servicing, upgrade, etc.). Before the maintenance, a user will likely need to power down the device. During or after maintenance, the power needs to be restored, and the system reset or tested. If the control buttons 120 are on an opposite side of the rack 200 than the access port, a user would have to continually disrupt their maintenance to go around the device to see or manipulate a panel on another side of the device. Depending on the location and arrangement of the device, access to a different side may not be convenient. Accordingly, power lines and circuit paths 240 are split within the rack 200 to provide independent control from at least two sides of the rack, and preferably opposite sides, and more preferably at or near an access panel.

As shown in FIG. 3, a back panel 130 of the rack 200 contains various connectors for peripheral attachments. The back panel 130 may include gripping surfaces 115, a power supply fan 140, power plug 145, master power switch 150, control buttons 120, peripheral plugs 155, and ventilation holes 135. The rack 200 has control buttons 120, such as a power button or switch, a reset button, and indicators to indicate power status as well as hard drive and network activity. The rack 200 may include built-in I/O ports (such as USB and headphone ports) on the front of the casing. The rack 200 will also include the wires 240 needed to connect these ports, switches and indicators to the motherboard 170. A power supply fan 140 exhausts the rack 200 to assist with system cooling. The removal of a back plane, the power supply fan 140, and the cooling fans 165 in the center of the rack 200 greatly increases the cooling efficiency of the rack 200 and improves heat management through removal of the back plane.

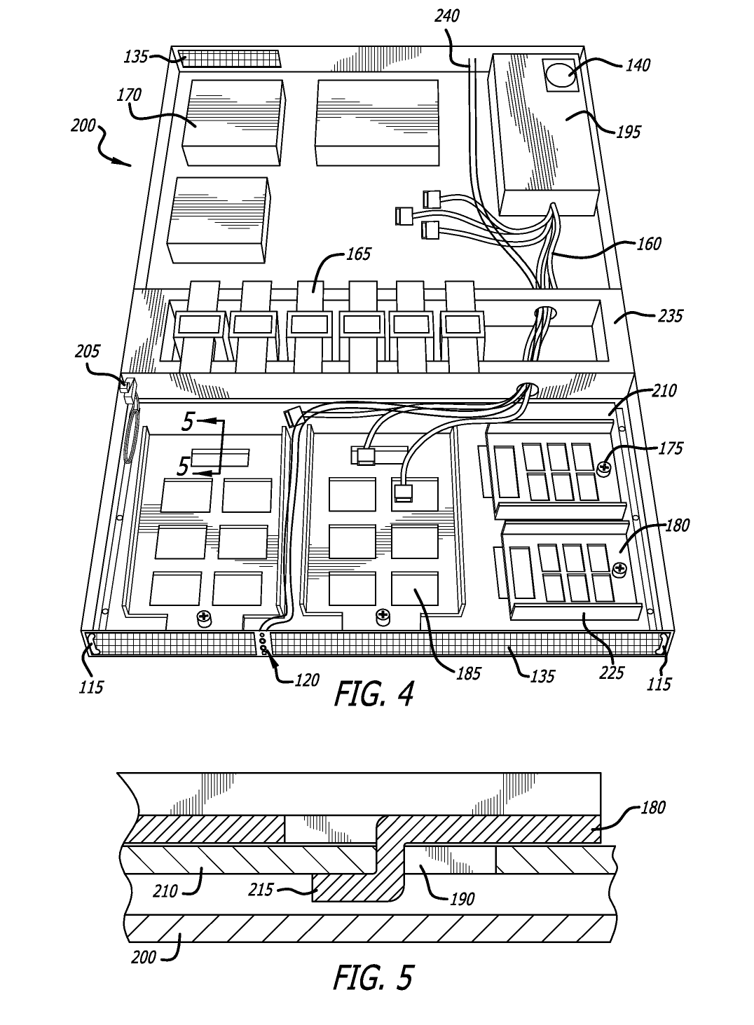

As shown in FIG. 4, a plurality of individual connectors 160 may be provided to connect one or more components, such as hard drives. The individual connectors 160 permit the layout and configuration of any attached components or hard drives to be dynamic. This allows a fully flexible hard drive installation of various sized (e.g. 3.5 and 2.5 inch) hard drives. Therefore, the chassis 100 may be reused as different components are removed, replaced, upgraded, etc. Frames 180 may be used to secure the individual hard drives to the rack 200. For example, an area of the rack 200 may be dedicated for hard drives. This area may include two frames 180 for 2.5 inch hard drives and two frames 180 for 3 inch hard drives. As needs change, one or more of the 2.5 inch hard drives may be replaced by one or more other hard drives of different sizes and/or configurations by simply removing the hard drive, disconnecting its connector 160, and replacing the frame 180 for one of the appropriate size of the replacement drive. The frames 180 may be configured or arranged to further improve circulation through the rack 200.

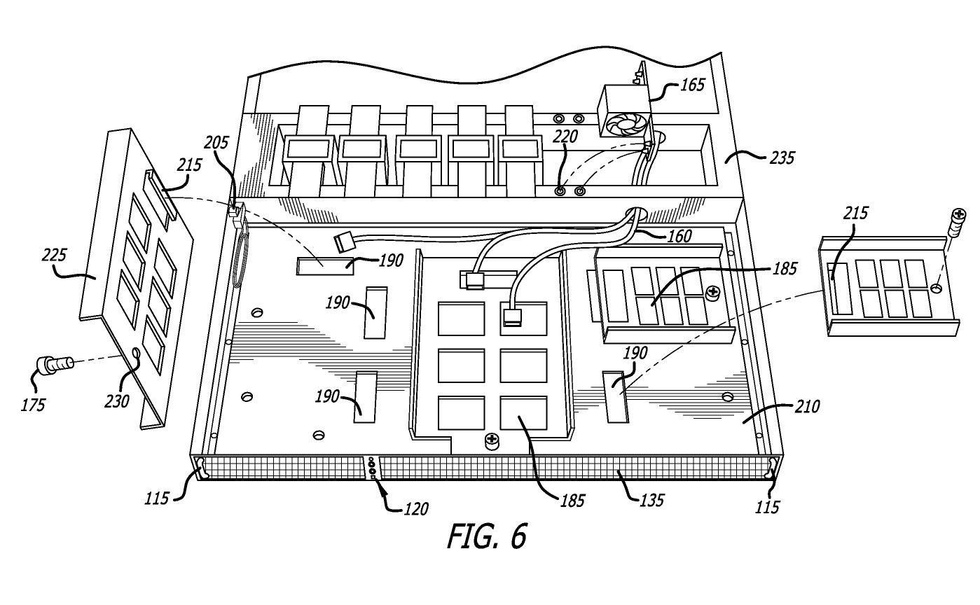

For example, the dedicated hard drive area of the rack 200 may include a hard drive base frame 210 for attaching individual hard drive frames 180 in various arrangements. An exemplary arrangement is seen in FIGS. 4 and 6. FIG. 6 illustrates a portion of a base frame 210 to accommodate different individual hard drive frames 180 as shown in FIG. 4. A generally planar piece of metal may create the hard drive base frame 210. One or more holes 185 may be cut out to improve ventilation to the attached hard drive. An individual hard drive frame 180 is a generally planar piece of metal with one or more flanges 225 at a peripheral edge to retain a hard drive. The individual frame 180 may also include holes 185 for ventilation. Screw holes 230 may be incorporated into both the individual frame 180 and the hard drive base frame 210 to attach the two together. Because of the arrangement of available screw holes, the individual frame 180 may be orientated and/or arranged in various patterns along and/or around the base frame 210 along with other individual frames 180 of different or common size.

The rack 200 is used for assembling computer parts such as a central processing unit, a motherboard, an interface card(s), a power supply, connection cables, a fan(s), a buzzer and a data storage peripheral(s). The data storage peripheral, which maybe a hard disk or a CD-ROM drive, is connected to the motherboard or the interface card with connection ports thereon. An eSATA connection port of the motherboard or the interface card is suitable for connecting a hard disk or a CD-drive. The body may be decorated with paintings or printed patterns suitable for marketing selling promotion and may comprise a top cover, front cover and side covers. It is also preferred that the body further comprises at least one driver cover for an aesthetic appearance.

The cooling fans 165 within the rack increase the cooling efficiency and airflow of the chassis 100. The fans are shown in FIG. 4 mounted to the center of the rack 200, but may be moved to different locations or orientations, as shown in FIG. 6. Close to the cooling fan 165 area is an optional attached rolling pin 205, connected to wires 240. Once the rack 200 is inserted into the casing 105, the rolling pin 205 clicks into a corresponding indent 255 in the interior of the casing 105. A wire 240 connected to the rolling pin 205 alerts a user that the rack 200 is secured into the casing 105.

As seen in FIG. 5, individual frames 180 may be mated with the base frame 210. In an exemplary embodiment, the individual frame 180 may also include a flanged lip 215 to mate with a gap 190 either along a peripheral edge or within the base frame 210. The flanged lip 215 may generally extend out of the plane of the individual frame 180 and then traverse generally parallel to it to create a hooked ledge to wrap around an edge of the gap 190. With such a connection, the individual frames 180 may be securely attached to the base frame 210 while the flanged lip 215 is mated with the gap 190, and also be easily alterable and moved to another location or orientation on the base frame 210.

FIG. 6 illustrates the dynamic nature of the various components, particularly the cooling fans 165 and hard drive frames 180. The cooling fans 165, by way of an exemplary pin and rubber connection 220 or any other removable mating connection, may be removed and rearranged within the computer chassis. The rubber and pin connection provided on the cooling fan back plate 235, allows for the location, orientation, and number of cooling fans 165 to be altered. Thus, the location of the cooling fans 165, among the many rubber slots, and orientation, from forward-facing to rear-facing, may be changed with ease. Similarly, the location and orientation of the hard drive frames 180 is dynamic. Each hard drive frame 180 may be secured to the hard drive base frame 210 by screws 175 and a flanged lip 215 secured under a gap 190 in the hard drive base frame 210. As illustrated, two larger hard drive frames 180 are arranged with two smaller hard drive frames 180, although other combinations are contemplated. As an example, the larger hard drive frames 180 may be secured to the left, middle, or right on the hard drive base frame 210. The smaller hard drive frames 180 may also be secured to the left, middle, or right on the hard drive base frame 210, and may face the left or right direction. As shown in FIG. 6, the smaller hard drive frames 180 may be placed in the gap closer to the left edge of the rack 200 so that the screw 175 is located to the right of the gap 190, or the smaller hard drive frame 180 may be placed in the gap 190 closer to the right edge of the rack 200, so that the screw 175 is located to the left of the gap 190.

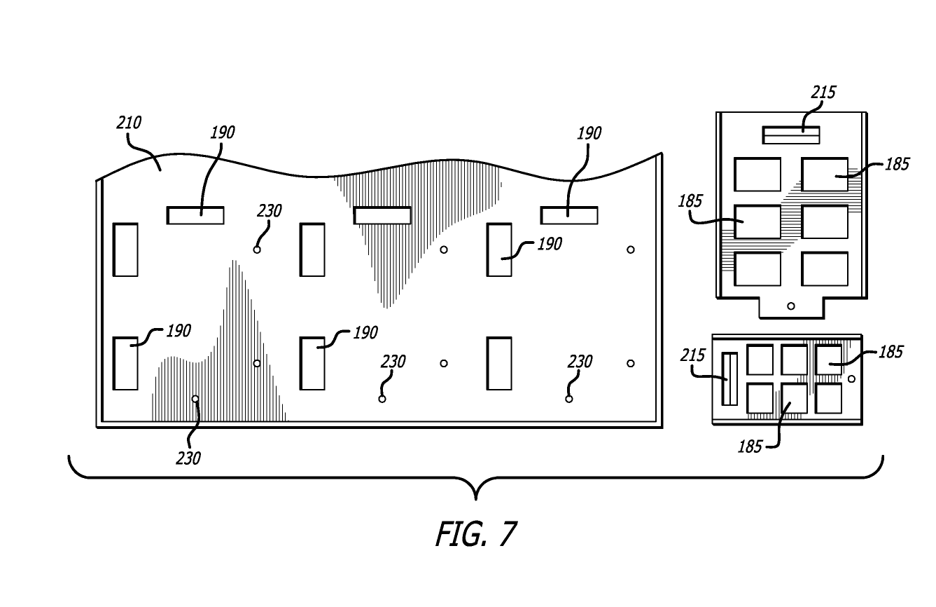

An exemplary hard drive base frame 210 is shown in FIG. 7. In one embodiment, the hard drive base frame 210 is disconnected from the individual hard drive frames 180. As seen, various sizes and orientations of hard drives may be accommodated by the arrangement of screw holes 230 and gaps 190. For example, one larger (e.g. 3.5 inch) hard drive frame 180 may be orientated across a section of the base frame 210. Alternatively, two smaller (e.g. 2.5 inch) hard drive frames 180 may be orientated along another section of the base frame 210 side by side. The same or a different pattern of screw holes 230, gaps 190, and vent holes 185 may be repeated along the length of the base frame 210 to accommodate additional hard drives.

The rack 200 may optionally include a mechanism to alert a user that the rack 200 is securely inserted into the casing 105. FIGS. 8A and 8B illustrate the operation of an optional roller sensor 205. FIG. 8A shows the roller sensor 205 as it is inserted into the casing 105. When under the paneling of the casing 105, the roller sensor 205 is depressed, in turn depressing the sensor button 250. In FIG. 8B, when the roller sensor reaches the indent 255 in the casing 105, the roller sensor 205 is raised, thus raising the sensor button 250. When the sensor button 250 is raised, it sends a signal through the wires 240, altering the user that the rack 200 has been properly installed in the casing 105. This may be done through the control buttons 120, such as by causing indicator lights to flash, on the front panel 125 and/or back panel 130 of the rack 200.

FIG. 9 shows one such arrangement of additional hard drives. In an exemplary embodiment, the base plate 210 may accommodate 12 larger-sized hard drives 245 arranged side by side. If the 12 larger-sized hard drives were removed, 24 smaller hard drive frames 180 could be inserted in their place. Any number of hard drive frame combinations could be arranged using the specified chassis. The components are generally arranged as described previously, with ventilation holes 135, gripping surfaces 115, power supply fan 140, control buttons 120, internal components 170, and peripheral plugs 155. However, the center cooling fans 165 differ slightly. In FIG. 9, the cooling fans 165 are attached to the cooling fan back plate through a rubber and pin, or other, connection at one end of the cooling fan 165. Also, each cooling fan 165 arrangement may have two fans stacked back to back, so as to provide more cooling capacity. Still, the cooling fans 165 location, orientation, and number is dynamic.

Exemplary features of an exemplary computer chassis are shown and described. It is understood that these features may be used singularly or in any combination, recombination, or sub-combination as dictated by the needs of the individual system. Also, as described above, the system permits dynamic configuration of hard drives by arranging removable individual frames. Other components may also be used in place of the hard drives, as the hard drives are used simply as an exemplary embodiment. Also, as shown and described, dedicated areas are used for one or more component types within the system. These areas may not be so limited, and may be formed in any location and/or arrangement as needed by the system requirements. Additional or fewer ventilation holes may also be incorporated into the system. Additional access panels, ports, and/or open sides may also be included to provide easy access to the interior of the rack on one or more sides. The device is not intended to be limited to the panels on opposite sides, but may include access on any one or more sides. “Connect,” “coupled,” “attached” and other such relational words are intended to include various direct and indirect connections and not those specifically identified. For example, screwing, bolding, hook and loop, rivets, button, pins, etc. are alternative configurations as well as other known forms of connection, all of which are considered alternatives.

1. A computer chassis, comprising:
a casing, having one or more open sides and being connected to a cabinet;
a rack slidably inserted into the casing;
gripping surfaces secured to one or more sides of the rack; and
two or more individual connectors attached at a first end to a power supply and unattached at a second end;
wherein the rack further comprises two or more variable components.

2. The computer chassis of claim 1, wherein the rack comprises a first access panel on one side of the rack and a second access panel on another side of the rack.

3. The computer chassis of claim 2, wherein the first access panel and the second access panel are on opposite sides of the rack.

4. The computer chassis of claim 1, wherein the rack does not include a back plane.

5. The computer chassis of claim 1, wherein the two or more individual connectors are for connection to two or more hard drives.

6. The computer chassis of claim 1, wherein the rack comprises control buttons on two or more sides of the rack.

7. The computer chassis of claim 1, wherein the rack comprises light indicators on two or more sides of the rack.

8. The computer chassis of claim 1, wherein the rack may be inserted into the casing from two or more sides of the casing.

9. The computer chassis of claim 1, wherein the rack is fully enclosed when positioned within the casing except for ventilation holes providing an air flow through the rack.

10. The computer chassis of claim 1, wherein the variable components comprise one or more removable cooling fans.

11. The computer chassis of claim 1, wherein the variable components comprise one or more removable hard disk frames.

12. The computer chassis of claim 11, wherein the one or more removable hard disk frames further comprise ventilation holes therein.

13. The computer chassis of claim 1, wherein the rack further comprises one or more rolling sensors.
